(19) United States
(12) Patent Application Publication
(10) Pub. No.: US 2011/0236567 A1
(43) Pub. Date: Sep. 29, 2011

(54) METHOD OF FORMING ELECTRODE

(75) Inventor: Kazutaka KURIKI, Ebina (JP)

(73) Assignee: SEMICONDUCTOR ENERGY LABORATORY CO., LTD., Atsugi-shi (JP)

(21) Appl. No.: 13/038,413

(22) Filed: Mar. 2, 2011

(30) Foreign Application Priority Data
Mar. 26, 2010 (JP) 2010-072971

(51) Int. Cl. B05D 5/12; B05D 3/00; C23C 14/36; C23C 14/06

(52) U.S. Cl. 427/122; 204/192.26

(57) ABSTRACT

Provided are a method of forming a carbon film which has a reduced number of steps and improved productivity without needing a high-temperature process, and a method of forming an electrode which does not need a binder. A fluororesin film is formed on a surface of a collector, and a surface of the fluororesin film is contacted with an alkali metal such as lithium to perform defluorination and then washed with acid. By this processing, lithium (Li) chemically reacts with fluorine (F) in the fluororesin film, and lithium fluoride (LiF) is generated. Consequently, the fluororesin film is defluorinated, whereby an electrode having a carbon film is formed.

### BACKGROUND OF THE INVENTION

1. Field of the Invention

The technical field relates to a method of forming an electrode of a power storage device.

2. Description of the Related Art

An electrode having a film containing carbon (also referred to as a carbon film) in a power storage device such as an electric double layer capacitor (EDLC) or a lithium ion capacitor (LIC) is completed by two processes: a process for forming the carbon film and a process for forming the electrode.

The process for forming, for example, activated carbon as the carbon film is divided into the following steps: (1) carbonization, (2) particle size adjustment, (3) activation (stimulation), (4) washing, (5) drying, and (6) crush.

The process for forming the electrode is divided into the following steps: (1) slurry production, (2) application, (3) drying, and (4) press.

In Patent Document 1, a method of producing an activated carbon electrode of an electric double layer capacitor is proposed.

### REFERENCE

### Patent Document

Patent Document 1: Japanese Published Patent Application No. 2009-260177

### SUMMARY OF THE INVENTION

The process for forming activated carbon given above as an example of the carbon film involves a large number of steps and has low productivity. Further, the activation (stimulation) step needs a high-temperature process at about 1000° C.

In the application step for forming the electrode, the activated carbon needs to be mixed with a binder, and the discharge capacity per unit volume is reduced accordingly.

In view of the above, an object is to provide a method of forming a carbon film which has a reduced number of steps and improved productivity without needing a high-temperature process. Another object is to provide a method of forming an electrode which does not need a binder.

According to one embodiment of the present invention, a film including carbon (also referred to as a carbon film) is formed in such a manner that a fluororesin and an alkali metal are made to react and a metal fluoride is generated to remove fluorine from the fluororesin, and this carbon film is used for an electrode such as an anode or a cathode in a power storage device. A fluororesin film is formed on a surface of a collector, whereby defluorination can be performed on the surface of the collector. Thus, the carbon film can be formed on the collector without using a binder or the like.

One embodiment of the present invention is a method of forming an electrode having a carbon film by the steps of: forming a fluororesin film on a surface of a collector; contacting an alkali metal with a surface of the fluororesin film; and washing the surface of the fluororesin film with acid after the step of contacting the alkali metal. For example, lithium fluoride formed on the surface of the fluororesin film is made to react with dilute hydrochloric acid, so that the carbon film is obtained.

Another embodiment of the present invention is a method of forming an electrode having a carbon film by the steps of: forming a fluororesin film on a surface of a collector; immersing the fluororesin film in an electrolyte solution, in which an alkali metal salt is dissolved, to perform defluorination; and washing a surface of the fluororesin with acid after the step of immersing the fluororesin film.

The carbon film and the electrode can be formed at a time by a small number of steps, which leads to a productivity improvement.

### BRIEF DESCRIPTION OF THE DRAWINGS

FIG. 1 is a conceptual diagram of defluorination of a fluororesin film.

FIG. 2 shows a spectrum obtained by EDX analysis of a surface of a PTFE film.

FIG. 3 shows a spectrum obtained by EDX analysis of a portion at a depth of 120 nm from the surface of the PTFE film after lithium metal foil is contacted with the film.

FIG. 4 shows a spectrum obtained by EDX analysis of a portion at a depth of 500 nm from the surface of the PTFE film after lithium metal foil is contacted with the film.

### DETAILED DESCRIPTION OF THE INVENTION

### Embodiment 1

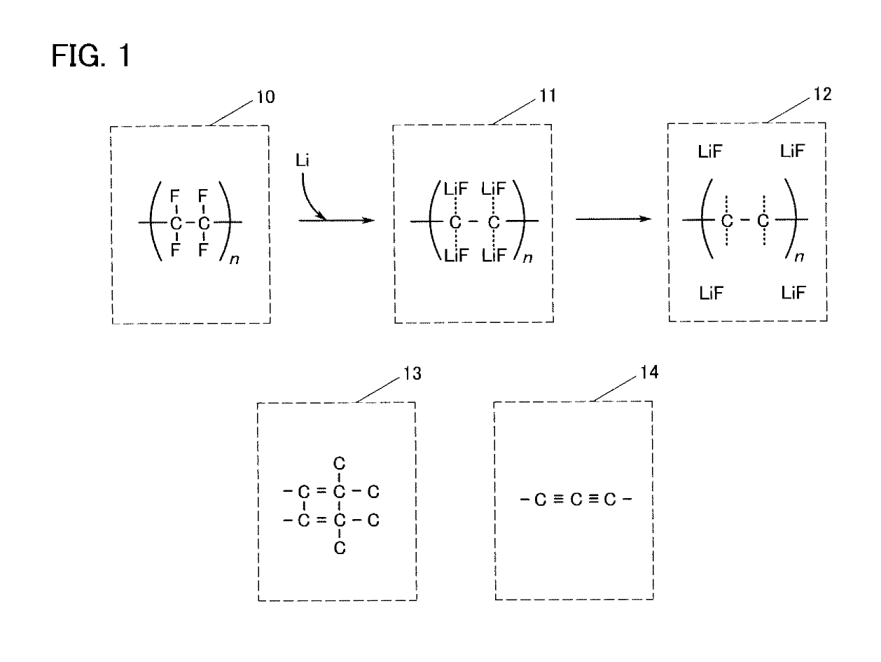

Description will be given of a method of forming an electrode having a carbon film which employs defluorination of a fluororesin film. FIG. 1 illustrates the concept of defluorination of the fluororesin film.

In a first step, the fluororesin film is formed on a surface of a collector by a sputtering method or the like. In FIG. 1, a structure 10 of the fluororesin film at this time is illustrated. Note that as the collector, a metal such as copper (Cu), titanium (Ti), or aluminum (Al) is used.

This fluororesin film is suitably formed under the conditions that sputtering is performed with a high-frequency discharge, the RF output power is greater than or equal to 400 [kW], the gas pressure is greater than or equal to 0.5 [Pa], and an argon (Ar) gas is used. With the use of such conditions, the fluororesin film is damaged in its formation, and consequently, the defluorination in the subsequent step is facilitated. Further, in the sputtering, a bias voltage may be applied.

In the structure 10 obtained in the first step, fluorine (F) is bonded to carbon (C). Fluorine (F) in the structure 10 is removed (defluorination is performed) to form a carbon film which can function as an electrode of a power storage device. The defluorination will be described below.

In a second step, an alkali metal such as lithium is contacted with the fluororesin film in order that the fluororesin film is defluorinated. As the alkali metal, sodium, potassium, or the like may be used. Then, lithium (Li) reduces the fluororesin film, and fluorine (F) is removed from the fluororesin film, whereby a defluorinated film is obtained. FIG. 1 illustrates a conceptual diagram of a structure 11 of the defluorinated film at this time.

In the structure 11 obtained in the second step, the fluororesin film is reduced by lithium (Li), and a substance having a bond between carbon atoms such as a carbon (C)-carbon (C) bond coexists with lithium fluoride (LiF) which is a by-product.

Next, in a third step, lithium fluoride (LiF) included in the defluorinated film is washed with acid such as dilute hydrochloric acid. As the acid, concentrated hydrochloric acid, hydrofluoric acid, or the like may be used. Then, lithium fluoride is removed from the defluorinated film, and a carbon film having the bond between carbon atoms such as a carbon (C)-carbon (C) bond is obtained. FIG. 1 illustrates a conceptual diagram of a structure 12 of the carbon film at this time. The bond between carbon atoms in the structure 12 may include a single bond, a double bond, a triple bond, or a structure in which these bonds are mixed, such as, specifically, a structure 13, a structure 14, or a structure in which they are mixed.

Next, in a fourth step, the collector and the carbon film are dried by heating. Note that the heating here is not necessarily needed. As the obtained carbon film, activated carbon, graphene, or the like can be given.

By the above-described steps, the electrode having the collector and the carbon film on the collector can be formed. This electrode can be used as an electrode of a power storage device.

Note that lithium used for the defluorination can be reused by kneading.

As described above, the electrode having the carbon film can be formed by a small number of steps without using a high-temperature process, which leads to a productivity improvement. Further, a binder is not provided, which enables an increase in capacity.

### Embodiment 2

Description will be given of a method of forming an electrode having a carbon film which employs defluorination of a fluororesin film, which is different from the method described in Embodiment 1.

In the second step, in order that the fluororesin film is defluorinated, the fluororesin film is immersed for 6 hours or more in a solution in which an alkali metal such as lithium is dissolved. As the alkali metal, sodium, potassium, or the like may be used. Then, lithium (Li) chemically reacts with fluorine (F) in the fluororesin film, and lithium fluoride (LiF) is generated.

In this step, lithium (Li) reduces the fluororesin film, and fluorine (F) is removed from the fluororesin film, so that the defluorinated film illustrated as the structure 11 in FIG. 1 is obtained. The other steps are performed as in Embodiment 1.

Examples of a solvent of the solution are: cyclic carbonates such as propylene carbonate (hereinafter referred to as PC), butylene carbonate (hereinafter referred to as BC), and vinylene carbonate (hereinafter referred to as VC); acyclic carbonates such as dimethyl carbonate (hereinafter referred to as DMC), ethylmethyl carbonate (hereinafter referred to as EMC), methylpropyl carbonate (hereinafter referred to as MPC), methylisobutyl carbonate (hereinafter referred to as MIBC), and dipropyl carbonate (hereinafter referred to as DPC); aliphatic carboxylic acid esters such as methyl formate, methyl acetate, methyl propionate, and ethyl propionate; γ-lactones such as γ-butyrolactone; acyclic ethers such as 1,2-dimethoxyethane (hereinafter referred to as DME), 1,2-diethoxyethane (hereinafter referred to as DEE), and ethoxymethoxy ethane (hereinafter referred to as EME); cyclic ethers such as tetrahydrofuran and 2-methyltetrahydrofuran; dimethylsulfoxide; 1,3-dioxolane; and alkyl phosphate esters such as trimethyl phosphate, triethyl phosphate, and trioctyl phosphate and fluorides thereof. These solvents can be used either alone or in combination. Further, when the above solvent includes naphthalene, the defluorination of the fluororesin film can be promoted.

### Embodiment 3

Description will be given of a method of forming an electrode having a carbon film which employs defluorination of a fluororesin film, which is different from the methods described in Embodiments 1 and 2.

In the second step, in order that the fluororesin film is defluorinated, the fluororesin film is immersed for 6 hours or more in an electrolyte solution, in which an alkali metal salt is dissolved, while an alkali metal such as lithium is contacted with the fluororesin film. As the alkali metal, sodium, potassium, or the like may be used. Then, lithium (Li) chemically reacts with fluorine (F) in the fluororesin film, and lithium fluoride (LiF) is generated.

In this step, lithium (Li) reduces the fluororesin film, and fluorine (F) is removed from the fluororesin film, so that the defluorinated film illustrated as the structure 11 in FIG. 1 is obtained.

Examples of the alkali metal salt that can be used in the electrolytic solution are lithium salts, for example, lithium chloride (LiCl), lithium fluoride (LiF), lithium perchlorate (LiClO₄), lithium fluoroborate (LiBF₄), lithium bis(trifluoromethanesulfonyl)imide LiN(SO₂CF₃)₂, lithium bis(pentafluoroethanesulfonyl)imide LiN(SO₂C₂F₅)₂, lithium trifluoromethansulfonate (LiCF₃SO₃), and the like. Other examples that may be similarly used as the alkali metal salt are potassium salts, sodium salts, and the like.

Examples of a solvent of the electrolytic solution are: cyclic carbonates such as PC, BC, and VC; acyclic carbonates such as DMC, EMC, MPC, MIBC, and DPC; aliphatic carboxylic acid esters such as methyl formate, methyl acetate, methyl propionate, and ethyl propionate; γ-lactones such as γ-butyrolactone; acyclic ethers such as DME, DEE, and EME; cyclic ethers such as tetrahydrofuran and 2-methyltetrahydrofuran; dimethylsulfoxide; 1,3-dioxolane; and alkyl phosphate esters such as trimethyl phosphate, triethyl phosphate, and trioctyl phosphate and fluorides thereof. These solvents can be used either alone or in combination.

### Example 1

A polytetrafluoroethylene (PTFE) film was deposited on a surface of a collector including aluminum (Al) by a sputtering method. Conditions for the deposition of this PTFE film were that the argon (Ar) gas flow rate was 50 [sccm], the gas pressure was 0.5 [Pa], the RF output power was 400 [kW], the formation rate was 9.3 [nm/min] at room temperature, and the thickness of the film was 700 [nm].

The deposited PTFE film was dried at 80° C. for 6 hours.

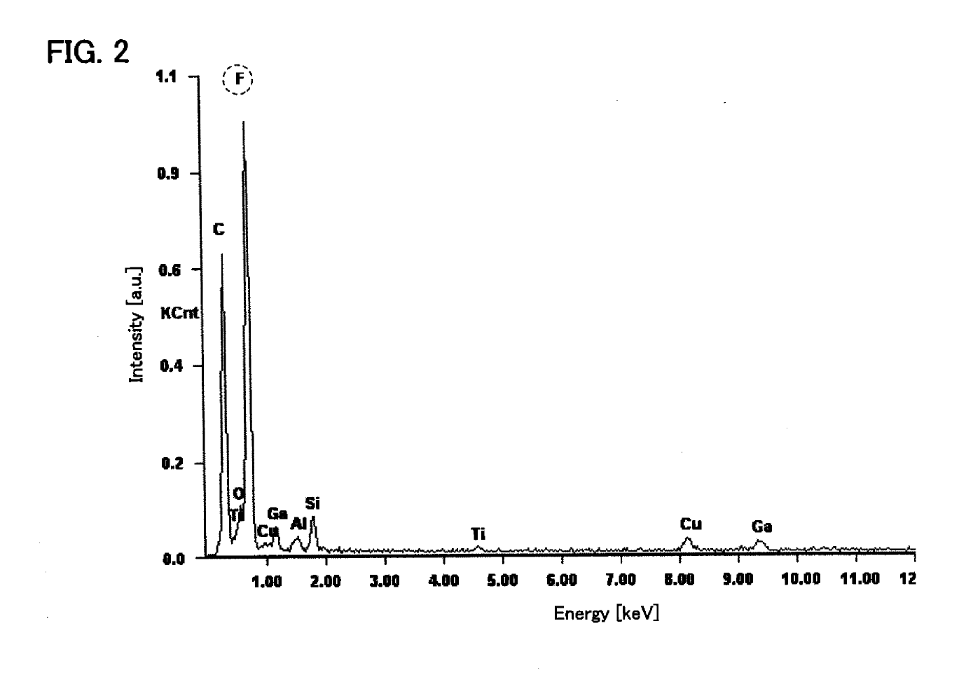

FIG. 2 shows a spectrum obtained by EDX (energy-dispersive X-ray) analysis of a surface of this PTFE film.

Next, in a gloved box containing an argon (Ar) atmosphere, lithium metal foil was contacted with the PTFE film, and pressure was uniformly applied to the whole film to press it.

Then, the lithium metal foil was separated from the PTFE film.

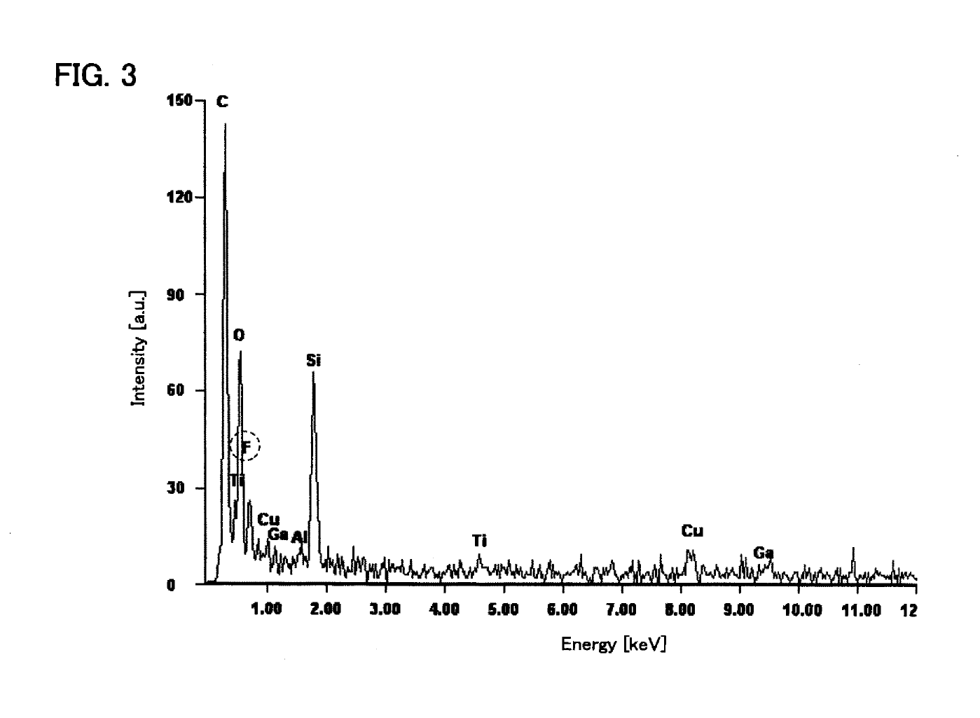

FIG. 3 shows a spectrum obtained by EDX analysis of a portion at a depth of 120 nm from the surface of the PTFE film after the lithium metal foil was contacted with the film. As compared to the spectrum illustrated in FIG. 2, the spectrum in FIG. 3 indicates that the fluorine (F) content in the film is small and defluorination occurs.

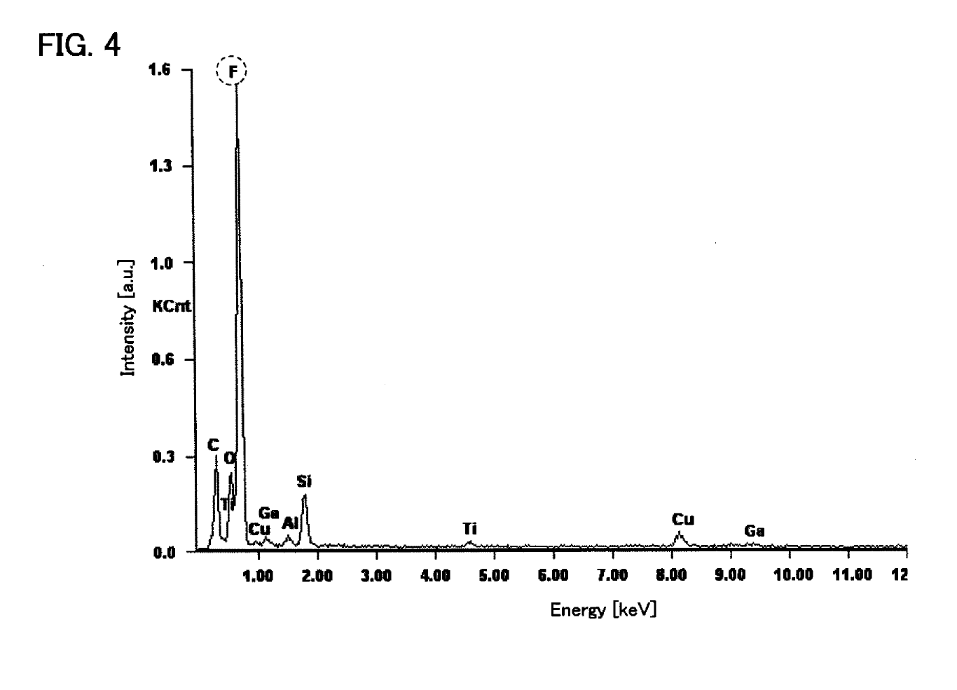

FIG. 4 shows a spectrum obtained by EDX analysis of a portion at a depth of 500 nm from the surface of the PTFE film after the lithium metal foil was contacted with the film. As compared to the spectrum illustrated in FIG. 2, the spectrum in FIG. 4 indicates that the fluorine (F) content in the film is large. Furthermore, an electron diffraction image (not illustrated) shows that lithium fluoride (LiF) might be formed.

This application is based on Japanese Patent Application serial no. 2010-072971 filed with the Japan Patent Office on Mar. 26, 2010, the entire contents of which are hereby incorporated by reference.

What is claimed is:

1. A method of forming an electrode comprising:
forming a fluororesin film on a surface of a collector;
contacting an alkali metal with a surface of the fluororesin film; and
washing the surface of the fluororesin film with acid, after contacting the alkali metal, thereby forming a film including carbon.

2. The method of forming the electrode according to claim 1, wherein the fluororesin film is a polytetrafluoroethylene film.

3. The method of forming the electrode according to claim 1,
wherein the fluororesin film is formed by sputtering with a high-frequency discharge, and
wherein, in the sputtering, an RF output power is greater than or equal to 400 kW, a gas pressure is greater than or equal to 0.5 Pa, and an argon gas is used.

4. The method of forming the electrode according to claim 1, wherein the collector comprises a metal selected from a group consisting of copper, titanium, and aluminum.

5. The method of forming the electrode according to claim 1, wherein the alkali metal is lithium.

6. The method of forming the electrode according to claim 1, wherein the acid is hydrochloric acid.

7. The method of forming the electrode according to claim 1, wherein the film including carbon is activated carbon.

8. The method of forming the electrode according to claim 1, further comprising:
drying the collector and the film including carbon by heating the collector and the film including carbon.

9. A method of forming an electrode comprising:
forming a fluororesin film on a surface of a collector;
contacting an alkali metal with a surface of the fluororesin film by immersing the fluororesin film in a solution in which the alkali metal is dissolved; and
washing the surface of the fluororesin film with acid, after contacting the alkali metal, thereby forming a film including carbon.

10. The method of forming the electrode according to claim 9, wherein the fluororesin film is a polytetrafluoroethylene film.

11. The method of forming the electrode according to claim 9,
wherein the fluororesin film is formed by sputtering with a high-frequency discharge, and
wherein, in the sputtering, an RF output power is greater than or equal to 400 kW, a gas pressure is greater than or equal to 0.5 Pa, and an argon gas is used.

12. The method of forming the electrode according to claim 9, wherein the collector comprises a metal selected from a group consisting of copper, titanium, and aluminum.

13. The method of forming the electrode according to claim 9, wherein the alkali metal is lithium.

14. The method of forming the electrode according to claim 9, wherein the acid is hydrochloric acid.

15. The method of forming the electrode according to claim 9, wherein the film including carbon is activated carbon.

16. The method of forming the electrode according to claim 9, further comprising:
drying the collector and the film including carbon by heating the collector and the film including carbon.

17. The method of forming the electrode according to claim 9, wherein the immersing the fluororesin film is performed for 6 hours or more.

18. The method of forming the electrode according to claim 9, wherein the solution includes naphthalene.

19. A method of forming an electrode comprising:
forming a fluororesin film on a surface of a collector;
contacting an alkali metal with a surface of the fluororesin film;
immersing the fluororesin film in an electrolyte solution in which an alkali metal salt is dissolved, while the surface of the fluororesin film is contacted with the alkali metal; and
washing the surface of the fluororesin film with acid, after contacting the alkali metal, thereby forming a film including carbon.

20. The method of forming the electrode according to claim 19, wherein the fluororesin film is a polytetrafluoroethylene film.

21. The method of forming the electrode according to claim 19,
wherein the fluororesin film is formed by sputtering with a high-frequency discharge, and
wherein, in the sputtering, an RF output power is greater than or equal to 400 kW, a gas pressure is greater than or equal to 0.5 Pa, and an argon gas is used.

22. The method of forming the electrode according to claim 19, wherein the collector comprises a metal selected from a group consisting of copper, titanium, and aluminum.

23. The method of forming the electrode according to claim 19, wherein the alkali metal is lithium.

24. The method of forming the electrode according to claim 19, wherein the acid is hydrochloric acid.

25. The method of forming the electrode according to claim 19, wherein the film including carbon is activated carbon.

26. The method of forming the electrode according to claim 19, further comprising:
drying the collector and the film including carbon by heating the collector and the film including carbon.

27. The method of forming the electrode according to claim 19, wherein the immersing the fluororesin film is performed for 6 hours or more.

28. The method of forming the electrode according to claim 19, wherein the alkali metal salt comprises a lithium salt, a potassium salt, or a sodium salt.
